(19) United States
(12) Patent Application Publication
(10) Pub. No.: US 2009/0165840 A1
(43) Pub. Date: Jul. 2, 2009

(54) SOLAR CELL MODULE AND METHOD OF MANUFACTURING THE SAME

(75) Inventors: Kazuya MURATA, Anpachi (JP); Mitsuhiro Matsumoto, Kobe (JP)

Correspondence Address: MOTS LAW, PLLC, 1629 K STREET N.W., SUITE 602, WASHINGTON, DC, 20006-1635, US

(73) Assignee: SANYO ELECTRIC CO., LTD., Moriguchi City (JP)

(21) Appl. No.: 12/270,978

(22) Filed: Nov. 14, 2008

(30) Foreign Application Priority Data
Dec. 27, 2007 (JP) JP2007-338221

(51) Int. Cl. H01L 31/042; H01L 31/18

(52) U.S. Cl. 136/244; 438/73; 257/E31.043

(57) ABSTRACT

A disclosed solar cell module includes: a translucent substrate; a translucent light-receiving-surface-side conductive layer formed on the substrate; a first semiconductor layer formed on the light-receiving-surface-side conductive layer; a transparent conductive layer formed on the first semiconductor layer; and a second semiconductor layer formed on the transparent conductive layer. The solar cell module has a first separating groove that separates the light-receiving-surface-side conductive layer into parts, and a transparent conductive layer separating groove formed continuously from the first separating groove and that separates the transparent conductive layer and the first semiconductor layer into parts. Those grooves are filled with the material of the second semiconductor layer. The transparent conductive layer separating groove at a side of the first separating groove is larger in width than the first separating groove at a side of the transparent conductive layer separating groove.

### CROSS REFERENCE TO RELATED APPLICATIONS

This application claims priority based on 35 USC 119 from prior Japanese Patent Application No. P2007-338221 filed on Dec. 27, 2007, entitled “SOLAR CELL MODULE AND METHOD OF MANUFACTURING THE SAME”, the entire contents of which are incorporated herein by reference.

### BACKGROUND OF THE INVENTION

1. Field of the Invention

The present invention relates to a solar cell module including a transparent conductive layer between a first semiconductor layer and a second semiconductor layer, as well as to a method of manufacturing the solar cell module.

2. Description of Related Art

In general, a thin film type solar cell module includes multiple solar cell elements electrically connected to each other in series. Each of the multiple solar cell elements includes: a light-receiving-surface-side conductive layer which is separated into parts by a first separating groove; a first semiconductor layer, a transparent conductive layer and a second semiconductor layer which are separated into parts by a second separation layer; and a back-surface-side conductive layer which is separated into parts by a third separating groove. Such a solar cell module is manufactured as follows.

Firstly, the light-receiving-surface-side conductive layer is formed on a translucent substrate, and then is partially removed by a laser beam to form the first separating groove. Subsequently, the first semiconductor layer, the transparent conductive layer and the second semiconductor layer are formed in this order on the light-receiving-surface-side conductive layer, and then are partially removed by a laser beam to form the second separating groove. Subsequently, the back-surface-side conductive layer is formed on the second semiconductor layer. Thereafter, by a laser beam, the transparent conductive layer, the second semiconductor layer and the back-surface-side conductive layer are partially removed at a location opposite to the first separating groove across the second separating groove. Thereby, the third separating groove is formed. Neighboring solar cell elements are electrically connected to each other in series with the back-surface-side conductive layer filled in the second separating groove.

Here, the transparent conductive layer functions as a reflection layer by which light having passed through the first semiconductor layer is partially reflected back to the first semiconductor layer. Such a transparent conductive layer is electrically connected to the back-surface-side conductive layer filled in the second separating groove. This causes a leakage current which flows from the transparent conductive layer to the back-surface-side conductive layer.

For the purpose of preventing such a leakage current, it is necessary to form, near the second separating groove, a transparent conductive layer separating groove that separates the transparent conductive layer. The following two methods of forming the transparent conductive layer separating groove have been proposed.

In a first method disclosed in Japanese Patent Application Laid-open Publication No. Hei. 9-129903, the light-receiving-surface-side conductive layer, the first conductive layer and the transparent conductive layer are formed in this order on the translucent substrate. Thereafter, the light-receiving-surface-side conductive layer, the first conductive layer and the transparent conductive layer are partially removed at the same time. This makes it possible to concurrently form the first separating groove configured to separate the light-receiving-surface-side into parts and the transparent conductive layer separating groove configured to separate the transparent conductive layer and the first semiconductor layer into parts.

In a second method disclosed in Japanese Patent Application Laid-open Publication No. 2002-261308 (corresponding to U.S. Pat. No. 6,632,993), the first semiconductor layer and the transparent conductive layer are partially removed between the first separating groove and the second separating groove. Thereby, the transparent conductive layer separating groove that separates the first conductive layer and the transparent conductive layer into parts is formed.

However, the two methods have the following problems. Specifically, in the first method, the first separating groove is filled with the second semiconductor layer because the first separating groove and the transparent conductive layer separating groove are continuous. As a result, the second semiconductor layer and the translucent substrate are in contact with each other. However, the second semiconductor layer has weak adhesiveness to glass or plastic, which is essentially contained in the translucent substrate. This causes a problem that the second semiconductor layer is delaminated from the translucent substrate.

In the second method, the transparent conductive layer separating groove is filled with the second semiconductor layer. For this reason, the second semiconductor layer and the light-receiving-surface-side conductive layer are in contact with each other. This contact may form a conductive path near the interface between the light-receiving-surface-side conductive layer and the second semiconductor layer. The formation of such a conductive path causes a problem that the separated parts of the transparent conductive layer may be electrically connected to each other.

### SUMMARY OF THE INVENTION

An aspect of the invention provides a solar cell module that includes: a translucent substrate; a translucent light-receiving-surface-side conductive layer formed on a principal surface of the substrate; a first semiconductor layer formed on a principal surface of the light-receiving-surface-side conductive layer; a transparent conductive layer formed on a principal surface of the first semiconductor layer; a second semiconductor layer formed on a principal surface of the transparent conductive layer; a back-surface-side conductive layer formed on a principal surface of the second semiconductor layer; a first separating groove configure to separate the light-receiving-surface-side conductive layer into parts, the first separating groove being filled with a material for the second semiconductor layer; a second separating groove configured to separate the first semiconductor layer, the transparent conductive layer and the second semiconductor layer into parts, the second separating groove being filled with a material for the back-surface-side conductive layer; a third separating groove formed in a location opposite to the first separating groove across the second separating groove and configured to separate the back-surface-side conductive layer, the second semiconductor layer and the transparent conductive layer into parts; and a transparent conductive layer separating groove formed continuously from the first separating groove and configured to separate the transparent conductive layer and the first semiconductor layer into parts, the transparent conductive layer separating groove being filled with the material for the second semiconductor layer, wherein the transparent conductive layer separating groove at a side of the first separating groove is larger in width than the first separating groove at a side of the transparent conductive layer separating groove.

### BRIEF DESCRIPTION OF THE DRAWINGS

FIG. 1 is a cross-sectional view of solar cell module 10 according to a first embodiment.

FIGS. 2A to 2D are diagrams showing a first method of manufacturing solar cell module 10 (Part 1).

FIGS. 3A and 3B are diagrams showing the first method of manufacturing solar cell module 10 (Part 2).

FIGS. 4A to 4F are diagrams showing a second method of manufacturing solar cell module 10 (Part 1).

FIGS. 5A to 5C are diagrams showing the second method of manufacturing solar cell module 10 (Part 2).

FIG. 6 is a cross-sectional view of solar cell module 10 according to a second embodiment.

FIGS. 7A to 7D are diagrams showing a third method of manufacturing solar cell module 10 (Part 1).

FIGS. 8A and 8B are diagrams showing the third method of manufacturing solar cell module 10 (Part 2).

FIGS. 9A to 9F are diagram showing a fourth method of manufacturing solar cell module 10 (Part 1).

FIGS. 10A to 10C are diagrams showing the fourth method of manufacturing solar cell module 10 (Part 2).

FIG. 11 is a cross-sectional view of a solar cell module 20 according to a comparative example.

### DETAILED DESCRIPTION OF EMBODIMENTS

An embodiment of the invention is described below by referring to the drawings. However, shapes, sizes, and positional relationships of respective components are merely schematically shown to an extent that the invention would be understood. In addition, the preferred embodiment is described below. However, materials, numerical conditions or the like of the respective components are simply shown as a preferred embodiment. Accordingly, the invention is not limited by the following embodiments but various modifications and deformation that can achieve the effects of the invention can be made without departing from the scope of the invention.

Prepositions, such as “on”, “over” and “above” may be defined with respect to a surface, for example a layer surface, regardless of that surface's orientation in space. The preposition “above” may be used in the specification and claims even if a layer is in contact with another layer. The preposition “on” may be used in the specification and claims when a layer is not in contact with another layer, for example, when there is an intervening layer between them.

### First Embodiment

### <Configuration of Solar Cell Module>

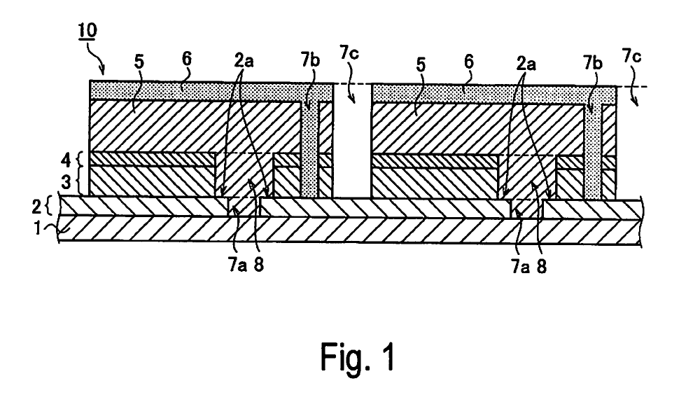

Descriptions will be provided hereinbelow for a configuration of a solar cell module according to a first embodiment by referring to FIG. 1.

FIG. 1 is a cross-sectional view of a solar cell module 10 according to the first embodiment.

As shown in FIG. 1, solar cell module 10 includes light-receiving-surface-side conductive layer 2, first semiconductor layer 3, transparent conductive layer 4, second semiconductor layer 5 and back-surface-side conductive layer 6 on a principal surface of substrate 1. Light-receiving-surface-side conductive layer 2, first semiconductor layer 3, transparent conductive layer 4, second semiconductor layer 5 and back-surface-side conductive layer 6 are formed in this order on the principal surface of substrate 1. In addition, solar cell module 10 includes first separating groove 7a, second separating groove 7b, third separating groove 7c and transparent conductive layer separating groove 8.

A transparent glass, plastic or the like may be used for substrate 1.

Light-receiving-surface-side conductive layer 2 is formed on the principal surface of substrate 1, and is conductive and transparent. A metallic oxide such as tin oxide (SnO₂), zinc oxide (ZnO), indium oxide (In₂O₃) or titanium oxide (TiO₂) may be used for light-receiving-surface-side conductive layer 2. Note that these metallic oxide may be doped with any one of fluorine (F), tin (Sn), aluminum (Al), ferrum (Fe), gallium (Ga), niobium (Nb) and the like.

First semiconductor layer 3 generates photogenerated carriers with light incident through light-receiving-surface-side conductive layer 2. In addition, first semiconductor layer 3 generates photogenerated carriers with light reflected from transparent conductive layer 4 to be described later. First semiconductor layer 3 includes a power-generating layer (referred to as an “i layer”) essentially containing an amorphous semiconductor. For example, first semiconductor layer 3 has a pin junction in which a p-type amorphous silicon semiconductor, an i-type amorphous silicon semiconductor and an n-type amorphous silicon semiconductor are formed in this order from the near side of substrate 1 (not illustrated).

Transparent conductive layer 4 is conductive and transmits part of light, which permeates first semiconductor layer 3, to second semiconductor layer 5. In addition, layer 4 reflects another part of light, which permeates first semiconductor layer 3, back to first semiconductor layer 3. A metallic oxide such as ZnO, ITO or TiO₂ may be used for transparent conductive layer 4. Transparent conductive layer 4 may be doped with a dopant such as aluminum. Furthermore, a layer such as a thin metal layer, a thin semiconductor layer or a combination of a thin insulating layer with a conductive layer, may be used for transparent conductive layer 4.

Second semiconductor layer 5 generates photogenerated carriers with incident light. Second semiconductor layer 5 includes a power-generating layer (i layer) essentially containing a microcrystalline semiconductor. For example, second semiconductor layer 5 has a pin junction in which a p-type microcrystalline silicon semiconductor, an i-type microcrystalline silicon semiconductor and an n-type microcrystalline silicon semiconductor are formed in this order from the near side of substrate 1 (not illustrated).

Back-surface-side conductive layer 6 is conductive. A metallic oxide such as ZnO or a metal such as argentum (Ag) may be used for back-surface-side conductive layer 6, but the material is not limited to these examples. For example, back-surface-side conductive layer 6 may have a configuration in which a layer containing ZnO and a layer containing Ag are sequentially formed from the near side of second semiconductor layer 5.

First separating groove 7a separates the light-receiving-surface-side conductive layer 2 into parts. First separating groove 7a is filled with second semiconductor layer 5.

Second separating groove 7b separates first semiconductor layer 3, transparent conductive layer 4 and second semiconductor layer 5 into parts on light-receiving-surface-side conductive layer 2. Part of the surface of light-receiving-surface-side conductive layer 2 appears through the bottom of second separating groove 7B. Second separating groove 7b is filled with back-surface-side conductive layer 6.

Third separating groove 7c separates back-surface-side conductive layer 6, second semiconductor layer 5, transparent conductive layer 4 and first semiconductor layer 3 into parts. Third separating groove 7c is formed in a location opposite to first separating groove 7a across second separating groove 7b. Note that third separating groove 7c may separate only back-surface-side conductive layer 6, second semiconductor layer 5 and transparent conductive layer 4 into parts without separating first semiconductor layer 3 into parts.

Transparent conductive layer separating groove 8 separates transparent conductive layer 4 and first semiconductor layer 3 into parts. Transparent conducive layer separating groove 8 is formed in a location where transparent conducive layer separating groove overlaps first separating groove 7a in a direction almost orthogonal to the principal surface of substrate 1. Transparent conductive layer separating groove 8 is filled with second semiconductor layer 5.

Here, the width of transparent conductive layer separating groove 8 on a first separating groove 7a side is wider than the width of first separating groove 7a on a transparent conductive layer separating groove 8 side. For this reason, the surface of light-receiving-surface-side conductive layer 2 and the surface of substrate 1 are partially exposed from the bottom of transparent conductive layer separating groove 8. Consequently, part of the surface of light-receiving-surface-side conductive layer 2 on the opposite side from substrate 1 is in contact with second semiconductor layer 5 filled in transparent conductive layer separating groove 8. Hereinafter, the part of the surface of light-receiving-surface-side conductive layer 2 on the opposite side from substrate 1, which is in contact with second semiconductor layer 5 filled with transparent conductive layer separating groove 8, will be referred to as “bond region 2a.” It is desirable that the width of transparent conductive layer separating groove 8 should be wider than the width of first separating groove 7a, but no more than 2.5 times of the width of first separating groove 7a.

### <Method of Manufacturing Solar Cell Module>

Descriptions will be provided hereinafter for two methods of manufacturing the solar cell module according to the first embodiment.

### (1) First Manufacturing Method

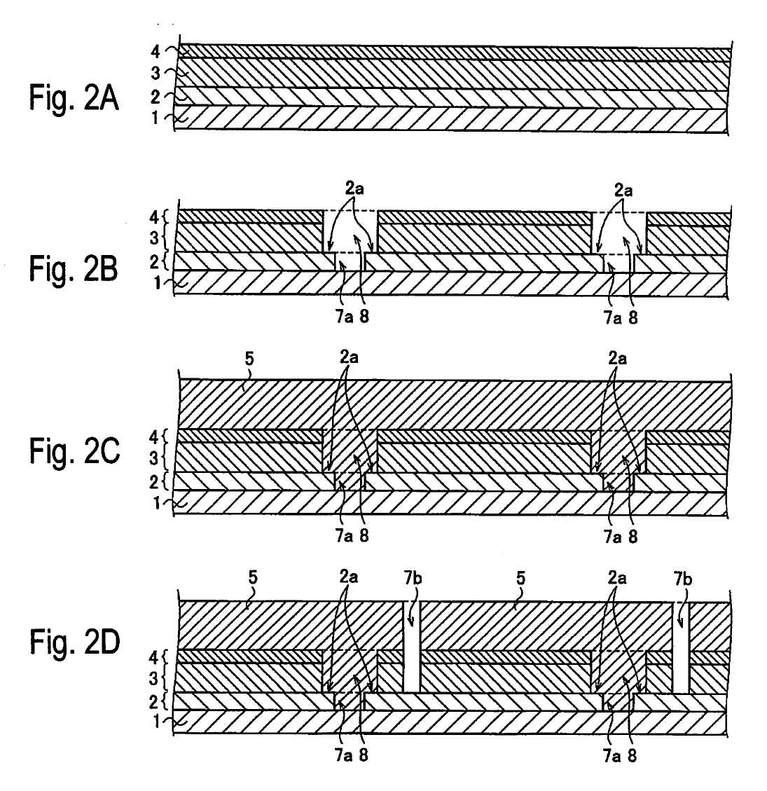

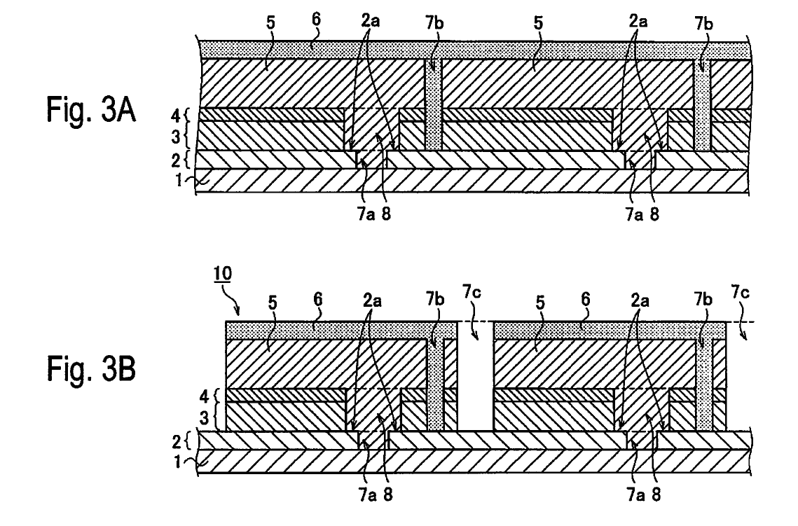

FIGS. 2A to 2D, FIGS. 3A and 3B are diagrams showing a process for manufacturing solar cell module 10 according to a first manufacturing method.

Firstly, as shown in FIG. 2A, light-receiving-surface-side conductive layer 2, first semiconductor layer 3 and transparent conductive layer 4 are sequentially formed on the principal surface of substrate 1. A CVD method such as an RF plasma CVD method may be used to form first semiconductor layer 3. In addition, a DC sputtering method or the like may be used to form transparent conductive layer 4.

Subsequently, as shown in FIG. 2B, transparent conductive layer separating groove 8 configured to separate transparent conductive layer 4 and first semiconductor layer 3 into parts is formed, and concurrently first separating groove 7a configured to separate light-receiving-surface-side conductive layer 2 into parts is formed. Specifically, Firstly, transparent conductive layer 4 and first semiconductor layer 3 are partially removed by irradiating a laser beam thereon to form transparent conductive layer separating groove 8. Subsequently, part of light-receiving-surface-side conductive layer 2 exposed in transparent conductive layer separating groove 8 is removed by irradiating a laser beam thereon to form first separating groove 7a. Here, first separating groove 7a is formed so as to be smaller in width than transparent conductive layer separating groove 8. With this configuration, as shown in FIG. 2B, part of the surface of light-receiving-surface-side conductive layer 2 on the opposite side from substrate 1 appears in transparent conductive layer separating groove 8.

Thereafter, as shown in FIG. 2C, second semiconductor layer 5 is formed on transparent conductive layer 4 by a CVD method such as an RF plasma CVD method. Concurrently, first separating groove 7a and transparent conductive layer separating groove 8 are filled with second semiconductor layer 5, respectively. Thereby, as shown in FIG. 2C, second semiconductor layer 5 filled in transparent conductive layer separating groove 8 is in contact with light-receiving-surface-side conductive layer 2 through bond region 2a.

Subsequently, first semiconductor layer 3, transparent conductive layer 4 and second semiconductor layer 5 are partially removed by irradiating a laser beam thereon. Thereby, as shown in FIG. 2D, second separating groove 7b configured to separate first semiconductor layer 3, transparent conductive layer 4 and second semiconductor layer 5 into parts is formed.

After that, as shown in FIG. 3A, back-surface-side conductive layer 6 is formed on second semiconductor layer 5 by a DC supporting method or the like. Concurrently, second separating groove 7b is filled with back-surface-side conductive layer 6.

Thereafter, in a location opposite to the first separating groove 7a across second separating groove 7b, back-surface-side conductive layer 6, second semiconductor layer 5, transparent conductive layer 4 and first semiconductor layer 3 are partially removed by irradiating a laser beam thereon. Thereby, as shown in FIG. 3B, third separating groove 7c configured to separate back-surface-side conductive layer 6, second semiconductor layer 5, transparent conductive layer 4 and first semiconductor layer 3 into parts is formed. Note that, alternatively, only back-surface-side conductive layer 6, second semiconductor layer 5 and transparent conductor layer 4 may be partially removed by irradiating a laser beam thereon, so that back-surface-side conductive layer 6, second semiconductor layer 5 and transparent conductor layer 4 are separated into parts. Through the foregoing process, solar cell module 10 is manufactured.

### (2) Second Manufacturing Method

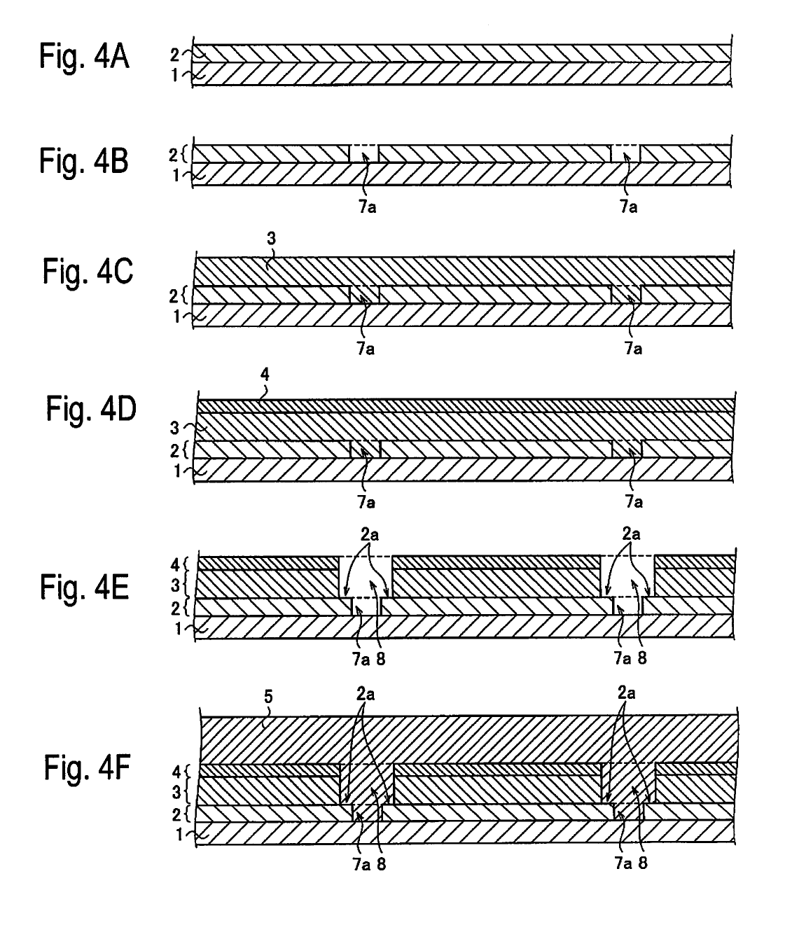

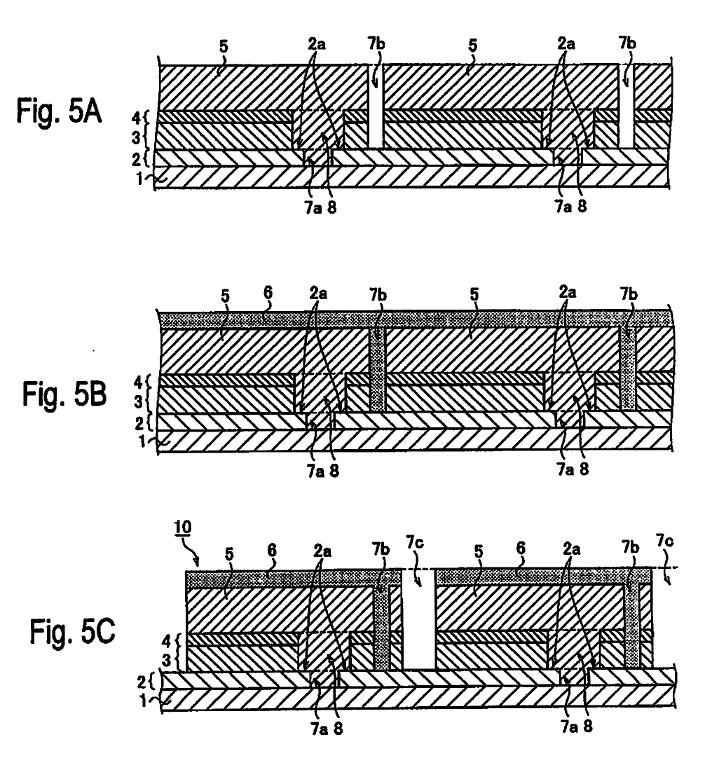

Descriptions will be provided hereinafter for a second method of manufacturing the solar cell module by referring to FIGS. 4A to 4F and FIGS. 5A to 5C. Note that the following descriptions will be provided mainly for the difference between the second method of manufacturing solar cell module 10 and the foregoing first method thereof. Specifically, in the foregoing first method of manufacturing solar cell module 10, light-receiving-surface-side conductive layer 2, first semiconductor layer 3 and transparent conductive layer 4 are formed on the principal surface of substrate 1. Thereafter, first separating groove 7a and transparent conductive layer separating groove 8 are formed. In contrast, in the second method of manufacturing solar cell module 10, first separating groove 7a is formed after only light-receiving-surface-side conductive layer 2 is formed on the principal surface of substrate 1. Thereafter, first semiconductor layer 3, transparent conductive layer 4 and transparent conductive layer separating groove 8 are sequentially formed.

Firstly, as shown in FIG. 4A, light-receiving-surface-side conductive layer 2 is formed on the principal surface of substrate 1.

Subsequently, part of light-receiving-surface-side conductive layer 2 is removed by irradiating a laser beam thereon. Thereby, as shown in FIG. 4B, first separating groove 7a configured to separate light-receiving-surface-side conductive 2 into parts is formed. Note that, light-receiving-surface-side conductive layer 2 may be formed using a mask, so as to leave first separating groove 7a therein.

Thereafter, as shown in FIG. 4C, by a CVD method such as an RF plasma CVD method, first semiconductor layer 3 is formed on light-receiving-surface-side conductive layer 2. Concurrently, first separating groove 7a is filled with first semiconductor layer 3.

After that, as shown in FIG. 4D, transparent conductive layer 4 is formed on first semiconductor layer 3 by a DC sputtering method or the like.

Subsequently, first semiconductor layer 3 filled in first separating groove 7a is removed by irradiating the laser beam thereon, and concurrently transparent conductive layer 4 and first semiconductor layer 3 are partially removed by irradiating the laser beam thereon. Thereby, as shown in FIG. 4E, transparent conductive layer separating groove 8 is formed which is continuous to first separating groove 7a and is configured to separate transparent conductive layer 4 and first semiconductor layer 3 into parts. Here, the width of transparent conductive layer separating groove 8 is set wider than the width of first separating groove 7a. Thereby, as shown in FIG. 4E, a surface of light-receiving-surface-side conductive layer 2 on the opposite side from the substrate 1 partially appears in transparent conductive layer separating groove 8.

Subsequently, as shown in FIG. 4F, second semiconductor layer 5 is formed on transparent conductive layer 4 by a CVD method such as an RF plasma CVD method. Concurrently, first separating groove 7a and transparent conductive layer separating groove 8 are filled with second semiconductor layer 5. Thereby, as shown in FIG. 4F, second semiconductor layer 5 filled in transparent conductive layer separating groove 8 is partially in contact with the light-receiving-surface-side conductive layer 2 through the bond region 2a.

Thereafter, as shown in FIGS. 5A to 5C, second separating groove 7b, back-surface-side conductive layer 6 and third separating groove 7c are sequentially formed. Steps respectively of forming second semiconductor layer 5, second separating groove 7b, back-surface-side conductive layer 6, and third separating groove 7c are the same as those included in the first method of manufacturing the solar cell module. For this reason, descriptions for the steps thereof will be omitted. With these steps, solar cell module 10 is manufactured.

### (Operation/Working Effect)

In solar cell module 10 according to the first embodiment, the width of transparent conductive layer separating groove 8 is formed wider than the width of first separating groove 7a. As a result, bond region 2a on the surface of light-receiving-surface-side conductive layer 2 on the opposite side from substrate 1 is in contact with second semiconductor layer 5 being filled in transparent conductive layer separating groove 8.

Since the microcrystalline semiconductor essentially contained in second semiconductor layer 5 does not firmly adhere to substrate 1, second semiconductor layer 5 is apt to be delaminated from substrate 1. However, in solar cell module 10 according to the first embodiment, second semiconductor layer 5 is in contact with, through bond region 2a, light-receiving-surface-side conductive layer 2 which firmly adheres to the microcrystalline semiconductor essentially contained in second semiconductor layer 5. This configuration is capable of preventing second semiconductor layer 5 from being delaminated from substrate 1. In addition, out of materials to be used as the main constituent of second semiconductor layer 5, the microcrystalline semiconductor most weakly adheres to the translucent substrate. However, solar cell module 10 according to the first embodiment makes it possible to prevent second semiconductor layer 5 from being delaminated from substrate 1 although the main constituent for second semiconductor layer 5 is the microcrystalline semiconductor.

Furthermore, since substrate 1 forms the bottom of first separating groove 7a continuing to transparent conductive layer separating groove 8, an conductive path, in which the parts of transparent conductive layer 4 being separated by transparent conductive layer separating groove 8 electrically connect to each other, is prevented from being formed. For this reason, the solar cell module 10 according to the first embodiment makes it possible to prevent a leakage current as well.

### Second Embodiment

Descriptions will be provided hereinbelow for a second embodiment. Note that the description will be made hereinafter mainly on the difference between the afore-mentioned first embodiment and the second embodiment.

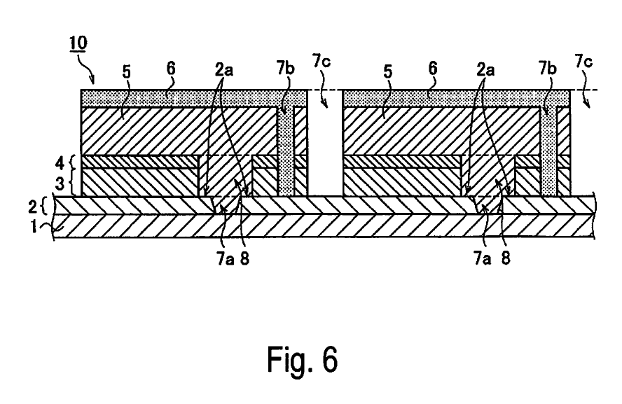

Descriptions will be provided hereinbelow for a configuration of a solar cell module according to a second embodiment by referring to FIG. 6.

FIG. 6 is a cross-sectional view of solar cell module 10 according to the second embodiment. In the second embodiment, as shown in FIG. 6, in first separating groove 7a, an angle between the inner wall of first separating groove 7a and the principal surface of substrate 1 is obtuse.

### (Method of Manufacturing Solar Cell Module)

Descriptions will be sequentially provided hereinbelow for two methods of manufacturing a solar cell module according to the second embodiment.

### (1) Third Manufacturing Method

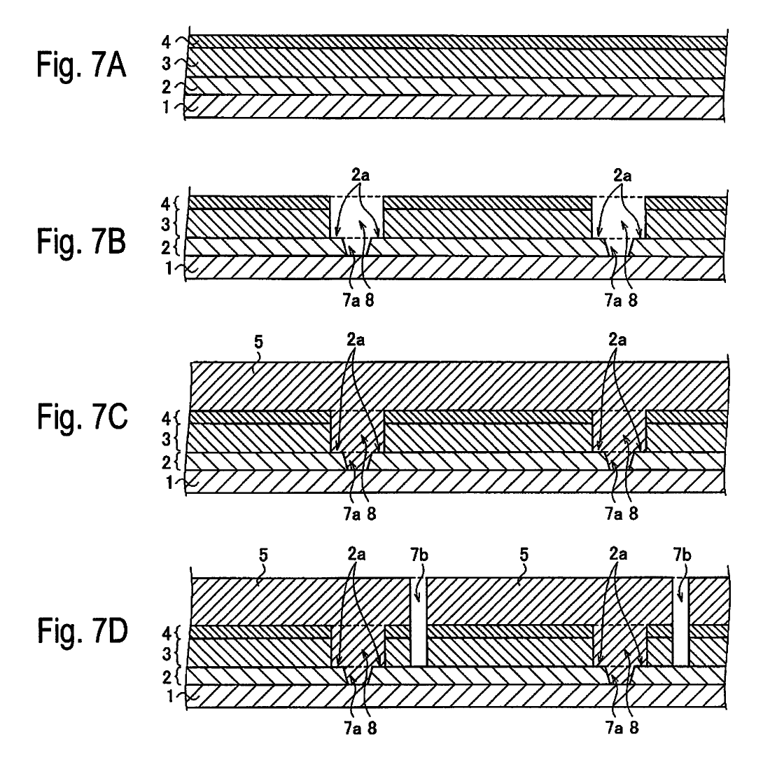

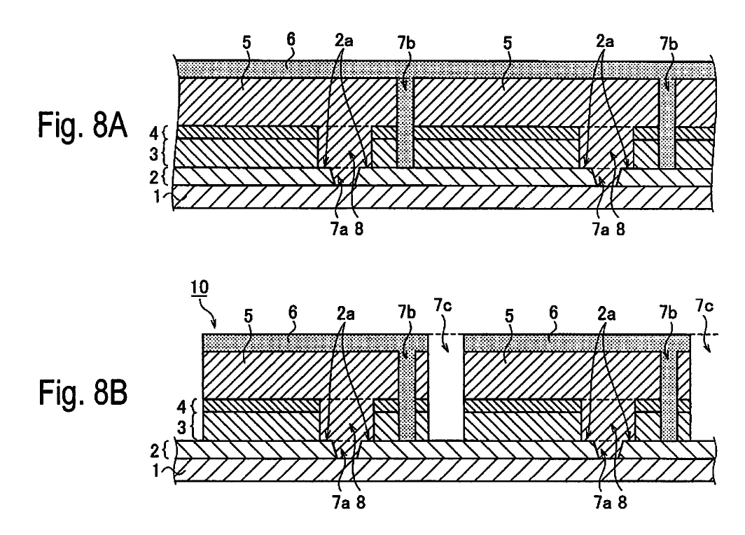

Descriptions will be provided hereinbelow for a third method of manufacturing solar cell module 10 according to the second embodiment by referring to FIGS. 7A to 7D, FIGS. 8A and 8B. Note that the following descriptions will be provided chiefly for the difference between the first manufacturing method according to the first embodiment and the third manufacturing method.

Firstly, as shown in FIG. 7A, light-receiving-surface-side conductive layer 2, first semiconductor layer 3 and transparent conductive layer 4 are sequentially formed on the principal surface of substrate 1. A CVD method such as an RF plasma CVD method may be used to form first semiconductor layer 3. In addition, a DC sputtering method or the like may be used to form transparent conductive layer 4.

Subsequently, as shown in FIG. 7B, transparent conductive layer separating groove 8 configured to separate transparent conductive layer 4 and first semiconductor layer 3 into parts is formed. Concurrently, first separating groove 7a configured to separate light-receiving-surface-side conductive layer 2 into parts is formed. In the third method of manufacturing solar cell module 10, when light-receiving-surface-side conductive layer 2 is removed by irradiating a laser beam thereon, the focus of the laser beam is defocused from the just focus condition and the output of the laser beam is increased. In first separating groove 7a, this irradiation arrangement makes the angle between the inner wall of first separating groove 7a and the principal surface of substrate 1 obtuse, as shown in FIG. 7B. Note that, like the first method of manufacturing solar cell module 10, in the third method, first separating groove 7a may be formed after transparent conductive layer separating groove 8 is formed, or before transparent conductive layer separating groove 8 is formed.

Thereafter, as shown in FIGS. 7C, 7D, 8A and 8B, second semiconductor layer 5, second separating groove 7b, back-surface-side conductive layer 6 and third separating groove 7c are sequentially formed. Steps respectively of forming second semiconductor layer 5, second separating groove 7b, back-surface-side conductive layer 6 and third separating groove 7c are the same as those included in the first method of manufacturing the solar cell module. For this reason, descriptions for the steps will be omitted here. With the foregoing steps, solar cell module 10 is manufactured.

### (2) Fourth Manufacturing Method

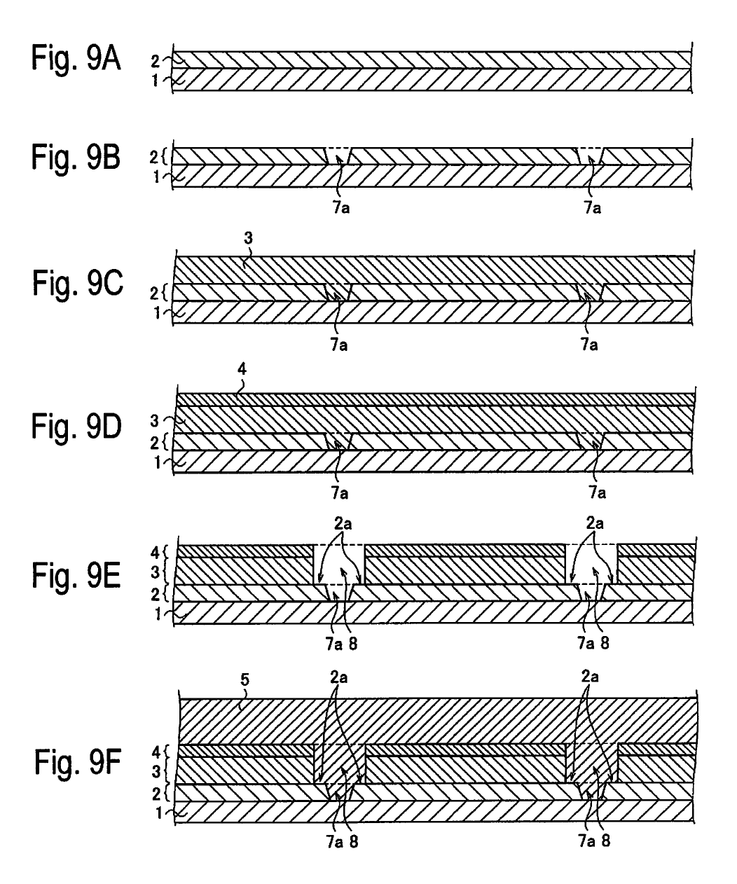

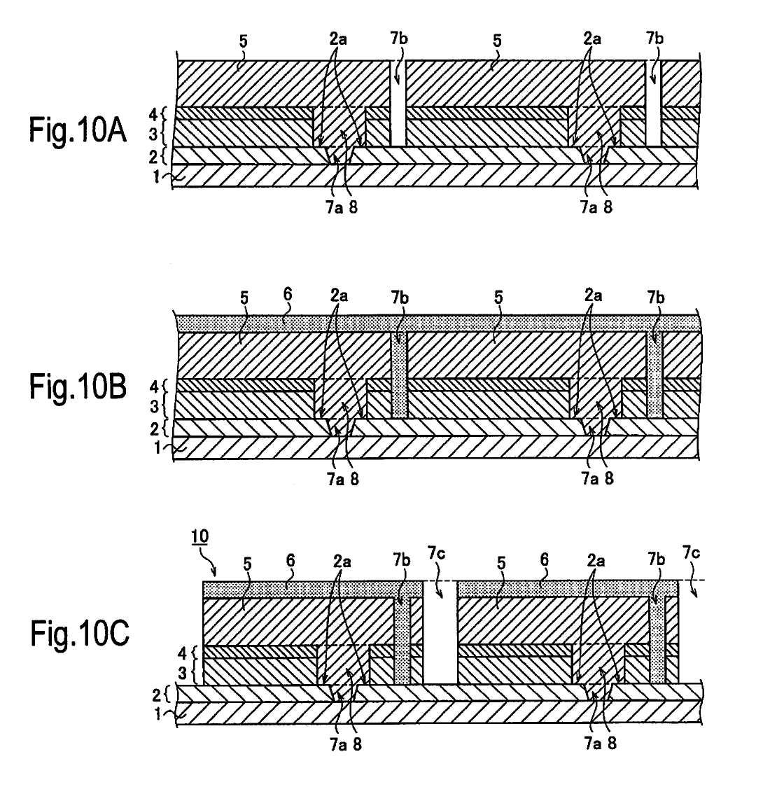

Descriptions will be provided hereinbelow for a fourth method of manufacturing solar cell module 10 according to the second embodiment by referring to FIGS. 9A to 9F and FIGS. 10A to 10C. Note that the following descriptions will be provided chiefly for the difference between the fourth manufacturing method from the second manufacturing method according to the first embodiment.

Firstly, as shown in FIG. 9A, light-receiving-surface-side conductive layer 2 is formed on the principal surface of substrate 1.

Subsequently, part of light-receiving-surface-side conductive layer 2 is removed by irradiating a laser beam thereon through substrate 1. Thereby, first separating groove 7a configured to separate light-receiving-surface-side conductive layer 2 into parts is formed. Here, the focus of the laser beam is defocused from the just focus condition and the output of the laser beam is increased. In first separating groove 7a, this irradiation arrangement makes the angle between the inner wall of first separating groove 7a and the principal surface of substrate 1 obtuse, as shown in FIG. 9B.

Thereafter, as shown in FIGS. 9C to 9F and FIGS. 10A to 10C, first semiconductor layer 3, transparent conductive layer 4, transparent conductive layer separating groove 8, second semiconductor layer 5, second separating groove 7b, back-surface-side conductive layer 6, third separating groove 7c are sequentially formed. Steps respectively of forming first semiconductor layer 3, transparent conductive layer 4, transparent conductive layer separating groove 8, second semiconductor layer 5, second separating groove 7b, back-surface-side conductive layer 6 and third separating groove 7c are the same as those included in the second method of manufacturing the solar cell module. For this reason, descriptions for these steps will be omitted here. With the foregoing steps, solar cell module 10 is manufactured.

### <Operation/Working-Effect>

In solar cell module 10 according to the second embodiment, in first separating groove 7a, the angle between the inner wall of first separating groove 7a and the principal surface of substrate 1 is obtuse, so that second semiconductor layer 5 can be formed easily in first separating groove 7a. Accordingly, this increases the crystallinity of formed second semiconductor layer 5 at the end portion of the bottom of first separating groove 7a, when the microcrystalline semiconductor is used for second semiconductor layer 5.

In general, a silicon semiconductor with a low crystallinity tends to be easily delaminated from substrate 1. In solar cell module 10 according to the second embodiment however, second semiconductor layer 5 has such improved crystallinity that second semiconductor layer 5 is less likely to be delaminated from substrate 1.

Furthermore, in solar cell module 10 according to the second embodiment, the area in which second semiconductor layer 5 is in contact with light-receiving-surface-side conductive layer 2 is increased. Consequently, second semiconductor layer 5 is less likely to be delaminated from substrate 1.

For the foregoing reasons, solar cell module 10 according to the second embodiment is capable of further increasing the effect or preventing second semiconductor layer 5 from being delaminated from substrate 1.

### Other Embodiments

The descriptions and drawings constituting parts of this disclosure shall not be construed as limiting the present invention, although the present invention has been described by the foregoing embodiments. This disclosure will make various alternative embodiments, examples and operating techniques clear to those skilled in the art.

For instance, the first and second embodiments of the present invention include a single pin junction in each of first semiconductor layer 3 and second semiconductor layer 5. However, the present invention is not limited to this configuration. Specifically, two or more pin junctions may be included in each of first semiconductor layer 3 and second semiconductor layer 5.

Furthermore, the first and second embodiments of the present invention have been described for the solar cell module configured to generate photogenerated carriers from light that enters back-surface-side conductive layer 6 from substrate 1. However, the present invention is not limited to this configuration. Specifically, by using a translucent material for back-surface-side conductive layer 6, the solar cell module may include a configuration in which the solar cell module generates photogenerated carriers with light incident to substrate 1 from back-surface-side conductive layer 6. In this case, first semiconductor layer 3 may include a power-generating layer (i layer) essentially containing microcrystalline semiconductor, whereas second semiconductor layer 5 may include a power-generating layer (i layer) essentially containing an amorphous semiconductor.

Moreover, first semiconductor layer 3 essentially contains the amorphous silicon semiconductor in the first and second embodiments of the present invention, but instead may essentially contain another type of semiconductor. Specifically, first semiconductor layer 3 may essentially contain a crystalline silicon semiconductor. Note that the crystalline silicon includes microcrystalline silicon and polycrystalline silicon. In addition, second semiconductor layer 5 essentially contains the microcrystalline silicon semiconductor in the first and second embodiments of the present invention, but instead may essentially contain another type of semiconductor. Specifically, second semiconductor layer 5 may essentially contain an amorphous silicon semiconductor.

In addition, in the first and second embodiments of the present invention, both of first semiconductor layer 3 and second semiconductor layer 5 respectively include the pin junctions. However, the present invention is not limited to this configuration. Specifically, at least one of first semiconductor layer 3 and second semiconductor layer 5 may include a pn junction obtained by stacking a p-type silicon semiconductor and an n-type silicon semiconductor on substrate 1.

Furthermore, in the first and second embodiments of the present invention, bond region 2a is provided to each of the two parts of light-receiving-surface-side conductive layer 2 which are located in the two sides of first separating groove 7. However, the present invention is not limited to this configuration. Specifically, bond region 2a may be provided to only any one of the two parts of light-receiving-surface-side conductive layer 2 which are located in the two sides of first separating groove 7.

Moreover, in the first method of manufacturing the solar cell module according to the first embodiment, description is provided for the manufacturing method in which the step of forming first separating groove 7a is performed after the step of forming transparent conductive layer separating groove 8. However, it is not necessary to perform these steps separately. Alternatively, the present invention may employ a single step of forming transparent conductive layer separating groove 8 and first separating groove 7a in parallel.

It goes without saying that, as described above, the present invention includes various embodiments and the like which have not been discussed in the description of the present invention. For this reason, the technical scope of the present invention is determined only by matters to define the present invention according to appended claims that can be regarded as appropriate from the foregoing descriptions.

### EXAMPLES

Specific descriptions will be provided hereinbelow for the solar cell module by citing examples. Note that the present invention is not limited to the following examples, and that the present invention can be variously carried out depending on the necessity without departing from the gist of the present invention.

### Example 1

Solar cell module 10 according to example 1 is manufactured by the first manufacturing method as follows.

Firstly, a SnO₂ layer (light-receiving-surface-side conductive layer 2) with an irregular structure is formed on glass substrate (substrate 1).

Subsequently, by the RF plasma CVD method, a first cell (first semiconductor layer 3) is formed on the SnO₂ layer (light-receiving-surface-side conductive layer 2). Specifically, the p-type amorphous silicon semiconductor, the i-type amorphous silicon semiconductor and the n-type amorphous silicon semiconductor are formed in this order to form the first cell (first semiconductor layer 3). The i-type amorphous silicon semiconductor is 250 nm in thickness.

Thereafter, by the DC sputtering method, a ZnO layer (transparent conductive layer 4) doped with an Al as a dopant is formed. The ZnO layer (transparent conductive layer 4) is 50 nm in thickness.

After that, the first cell (first semiconductor layer 3) and the ZnO layer (transparent conductive layer 4) are partially removed by irradiating an Nd:YAG laser beam thereon through the glass substrate (substrate 1). Thereby, the transparent conductive layer separating groove (transparent conductive layer separating groove 8) configured to separate the first cell (first semiconductor layer 3) and the ZnO layer (transparent conductive layer 4) into parts is formed. The second harmonics with a wavelength of 532 nm is used as the Nd:YAG laser beam. In addition, the transparent conductive layer separating groove (transparent conductive layer separating groove 8) is formed with a width of 70 μm by shifting the focus of the Nd:YAG laser beam. Note that, when a just focused laser beam is irradiated thereon, the transparent conductive layer separating groove (transparent conductive layer separating groove 8) is formed with a width of 50 μm.

Subsequently, part of the SnO₂ layer (light-receiving-surface-side conductive layer 2) which appears in the transparent conductive layer separating groove (transparent conductive layer separating groove 8) is removed by irradiating an Nd:YAG laser beam through the ZnO layer (transparent conductive layer 4). Thereby, the first separating groove (first separating groove 7a) is formed which is continuous to the transparent conductive layer separating groove (transparent conductive layer separating groove 8) and is configured to separate the SnO₂ layer (light-receiving-surface-side conductive layer 2) into parts. The fundamental harmonics with a wavelength of 1064 nm is used as the Nd:YAG laser beam. In addition, the first separating groove (first separating groove 7a) is 40 μm in width.

Thereafter, by the RF plasma CVD method, a second cell (second semiconductor layer 5) is formed on the ZnO layer (transparent conductive layer 4), and the first separating groove (first separating groove 7a) and the transparent conductive layer separating groove (transparent conductive layer separating groove 8) are filled with the second cell (second semiconductor layer 5). Specifically, the p-type microcrystalline silicon semiconductor, the i-type microcrystalline silicon semiconductor and the n-type microcrystalline silicon semiconductor are sequentially formed one after another thereon. The i-type microcrystalline silicon semiconductor is 2000 nm in thickness.

After that, the first cell (first semiconductor layer 3), the ZnO layer (transparent conductive layer 4) and the second cell (second semiconductor layer 5) are partially removed by irradiating an Nd:YAG laser beam on a vicinity of the transparent conductive layer separating groove (transparent conductive layer separating groove 8) through the glass substrate (substrate 1). Thereby, the second separating groove (second separating groove 7b) configured to separate the first cell (first semiconductor layer 3), the ZnO layer (transparent conductive layer 4) and the second cell (second semiconductor layer 5) into parts is formed. The second harmonics with a wavelength of 532 nm is used as the Nd:YAG laser beam. In addition, the second separating groove (second separating groove 7b) is 50 μm in width.

Subsequently, by the DC sputtering method, a ZnO layer and an Ag layer (back-surface-side conductive layer 6) is formed on the second cell (second semiconductor layer 5), and the second separating groove (second separating groove 7b) is filled with the ZnO layer and the Ag layer (back-surface-side conductive layer 6). The ZnO layer is doped with an Al as a dopant, and is 100 nm in thickness. In addition, the Ag layer is 300 nm in thickness.

Thereafter, the ZnO layer and the Ag layer (back-surface-side conductive layer 6), the second cell (second semiconductor layer 5), the ZnO layer (transparent conductive layer 4) and the first cell (first semiconductor layer 3) are partially removed by the irradiation of an Nd:YAG laser beam. Here, the Nd:YAG laser beam is irradiated, from the glass substrate (substrate 1), on the location opposite to the first separating groove (first separating groove 7a) across the second separating groove (second separating groove 7b). This results in the formation of the third separating groove (third separating groove 7c) configured to separate the ZnO layer and the Ag layer (back-surface-side conductive layer 6), the second cell (second semiconductor layer 5), the ZnO layer (transparent conductive layer 4) and the first cell (first conductive layer 3) into parts. The second harmonics with a wavelength of 532 nm is used as the Nd:YAG laser beam. In addition, the third separating groove (third separating groove 7c) is 50 μm in width.

As shown in FIG. 1, through these steps, formed is the solar cell module 10 according to example 1 which includes bond region 2a in contact with the second cell (second semiconductor layer 5) filled in the transparent conductive layer separating groove (transparent conductive layer separating groove 8) on the surface of the SnO₂ layer (light-receiving-surface-side conductive layer 2) on the opposite side from the glass substrate (substrate 1).

### Example 2

Solar cell module 10 according to example 2 is manufactured by the second manufacturing method as follows.

Firstly, a SnO₂ layer (light-receiving-surface-side conductive layer 2) with an irregular structure is formed on the glass substrate (substrate 1).

Subsequently, the SnO₂ layer (light-receiving-surface-side conductive layer 2) is removed by irradiating an Nd:YAG laser beam thereon through the SnO₂ layer (light-receiving-surface-side conductive layer 2). Thereby, the first separating groove (first separating groove 7a) configured to separate the SnO₂ layer (light-receiving-surface-side conductive layer 2) into parts is formed. The fundamental harmonics with a wavelength of 1064 nm is used as the Nd:YAG laser beam. In addition, the first separating groove (first separating groove 7a) is 40 μm in width.

Thereafter, by the RF plasma CVD method, a first cell (first semiconductor layer 3) is formed on the SnO₂ layer (light-receiving-surface-side conductive layer 2), and concurrently the first separating groove (first separating groove 7a) is filled with the first cell (first semiconductor layer 3). Specifically, the p-type amorphous silicon semiconductor, the i-type amorphous silicon semiconductor and the n-type amorphous silicon semiconductor are formed in this order thereon. The i-type amorphous silicon semiconductor is 250 nm in thickness.

After that, a ZnO layer (transparent conductive layer 4) doped with an Al as a dopant is formed on the first cell (first semiconductor layer 3) by the DC sputtering method. The ZnO layer (transparent conductive layer 4) is 50 nm in thickness.

Subsequently, the first cell (first semiconductor layer 3) and the ZnO layer (transparent conductive layer 4) are partially removed by irradiating an Nd:YAG laser beam through the glass substrate (substrate 1). Thereby, the transparent conductive layer separating groove (transparent conductive layer separating groove 8) is formed which is continuous to the first separating groove (first separating groove 7a), and is configured to separate the first cell (first semiconductor layer 3) and the ZnO layer (transparent conductive layer 4) into parts. The second harmonics with a wavelength of 532 nm is used as the Nd:YAG laser beam. In addition, the transparent conductive layer separating groove (transparent conductive layer separating groove 8) is formed with a width of 70 μm by shifting the focus of the Nd:YAG laser beam. Note that, when a just focused laser beam is irradiated thereon, the transparent conductive layer separating groove (transparent conductive layer separating groove 8) is formed with a width of 50 μm.

Thereafter, the second cell (second conductive layer 5), the second separating groove (second separating groove 7b), the ZnO layer and the Ag layer (back-surface-side conductive layer 6) and the third separating groove (third separating groove 7c) are formed in the same manner as those in the example 1.

As shown in FIG. 1, through these steps, formed is the solar cell module 10 according to example 2 which includes bond region 2a in contact with the second cell (second semiconductor layer 5) filled in the transparent conductive layer separating groove (transparent conductive layer separating groove 8) on the surface of the SnO₂ layer (light-receiving-surface-side conductive layer 2) on the opposite side from the glass substrate (substrate 1).

### Example 3

Solar cell module 10 according to example 3 is manufactured by the third manufacturing method as follows.

Firstly, a SnO₂ layer (light-receiving-surface-side conductive layer 2) with an irregular structure is formed on the glass substrate (substrate 1).

Subsequently, a first cell (first semiconductor layer 3) is formed on the SnO₂ layer (light-receiving-surface-side conductive layer 2) by the RF plasma CVD method. Specifically, the p-type amorphous silicon semiconductor, the i-type amorphous silicon semiconductor and the n-type amorphous silicon semiconductor are formed in this order thereon. The i-type amorphous silicon semiconductor is 250 nm in thickness.

After that, a ZnO layer (transparent conductive layer 4) doped with an Al as a dopant is formed on the first cell (first semiconductor layer 3) by the DC sputtering method. The ZnO layer (transparent conductive layer 4) is 50 nm in thickness.

Subsequently, the first cell (first semiconductor layer 3) and the ZnO layer (transparent conductive layer 4) are partially removed by irradiating an Nd:YAG laser beam through the glass substrate (substrate 1). Thereby, the transparent conductive layer separating groove (transparent conductive layer separating groove 8) configured to separate the first cell (first semiconductor layer 3) and the ZnO layer (transparent conductive layer 4) into parts is formed. The second harmonics with a wavelength of 532 nm is used as the Nd:YAG laser beam. In addition, the transparent conductive layer separating groove (transparent conductive layer separating groove 8) is formed with a width of 70 μm by shifting the focus of the Nd:YAG laser beam. Note that, when a just focused laser beam is irradiated thereon, the transparent conductive layer separating groove (transparent conductive layer separating groove 8) is formed with a width of 50 μm.

Thereafter, the SnO₂ layer (light-receiving-surface-side conductive layer 2) which appears in the transparent conductive layer separating groove (transparent conductive layer separating groove 8) is removed by irradiating an Nd:YAG laser beam thereon through the SnO₂ layer (light-receiving-surface-side conductive layer 2). At this time, the focus of the Nd:YAG laser beam is gradually defocused from the just focus condition and the output of the laser beam is gradually increased. Thereby, the first separating groove (first separating groove 7a) is formed which is continuous to the transparent conductive layer separating groove (transparent conductive layer separating groove 8), and is configured to separate the SnO₂ layer (light-receiving-surface-side conductive layer 2) into parts. In addition, the width of the first separating groove (first separating groove 7a) is 40 μm on a substrate 1 side, and 50 μm on a transparent conductive layer separating groove (transparent conductive layer separating groove 8) side. The fundamental harmonic with a wavelength of 1064 nm is used as the Nd:YAG laser beam. In addition, the output of the Nd:YAG laser beam is increased by 15%.

After that, the second cell (second semiconductor layer 5), the second separating groove (second separating groove 7b), the ZnO layer and the Ag layer (back-surface-side conductive layer 6) and the third separating groove (third separating groove 7c) are formed in the same manner as those in the example 1.

As shown in FIG. 6, through these steps, formed is the solar cell module 10 according to example 3 which includes bond region 2a in contact with the second cell (second semiconductor layer 5) filled in the transparent conductive layer separating groove (transparent conductive layer separating groove 8) on the surface of the SnO₂ layer (light-receiving-surface-side conductive layer 2) on the opposite side from the glass substrate (substrate 1), and in which the angle between the inner wall of first separating groove 7a and the principal surface of substrate 1 is obtuse in first separating groove 7a.

### COMPARATIVE EXAMPLE

Solar cell module 20 according to comparative example is manufactured as follows.

Firstly, a SnO₂ layer (light-receiving-surface-side conductive layer 2) with an irregular structure is formed on the glass substrate (substrate 1).

Subsequently, part of the SnO₂ layer (light-receiving-surface-side conductive layer 2) is removed by irradiating an Nd:YAG laser beam thereon through the SnO₂ layer (light-receiving-surface-side conductive layer 2). Thereby, the first separating groove (first separating groove 7a) configured to separate the SnO₂ layer (light-receiving-surface-side conductive layer 2) is formed. The fundamental harmonics with a wavelength of 1064 nm is used as the Nd:YAG laser beam. In addition, the first separating groove (first separating groove 7a) is 40 μm in width.

Thereafter, by the RF plasma CVD method, a first cell (first semiconductor layer 3) is formed on the SnO₂ layer (light-receiving-surface-side conductive layer 2), and the first separating groove (first separating groove 7a) is filled with the first cell (first semiconductor layer 3). Specifically, the p-type amorphous silicon semiconductor, the i-type amorphous silicon semiconductor and the n-type amorphous silicon semiconductor are formed in this order thereon. The i-type amorphous silicon semiconductor is 250 nm in thickness.

After that a ZnO layer (transparent conductive layer 4) doped with an Al as a dopant is formed on the first cell (first semiconductor layer 3) by the DC sputtering method. The ZnO layer (transparent conductive layer 4) is 50 nm in thickness.

Subsequently, the first cell (first semiconductor layer 3) and the ZnO layer (transparent conductive layer 4) are partially removed by irradiating an Nd:YAG laser beam in a position which does not overlap the first separating groove (first separating groove 7a) through a glass substrate (substrate 1). Thereby, the transparent conductive layer separating groove (transparent conductive layer separating groove 8) configured to separate the first cell (first semiconductor layer 3) and the ZnO layer (transparent conductive layer 4) into parts is formed. The second harmonics with a wavelength of 532 nm is used as the Nd:YAG laser beam. In addition, the transparent conductive layer separating groove (transparent conductive layer separating groove 8) is 50 μm in width.

Thereafter, by the RF plasma CVD method, a second cell (second semiconductor layer 5) is formed on the ZnO layer (transparent conductive layer 4), and the transparent conductive layer separating groove (transparent conductive layer separating groove 8) is filled with the second cell (second semiconductor layer 5). Specifically, the p-type microcrystalline silicon semiconductor, the i-type microcrystalline silicon semiconductor and the n-type microcrystalline silicon semiconductor are formed in this order thereon. The i-type microcrystalline silicon semiconductor is 2000 nm in thickness.

After that, the first cell (first semiconductor layer 3), the ZnO layer (transparent conductive layer 4) and the second cell (second semiconductor layer 5) are partially removed by irradiating, through a glass substrate (substrate 1), an Nd:YAG laser beam thereon in a position on the opposite side of the transparent conductive layer separating groove (transparent conductive layer separating groove 8) from the first separating groove (first separating groove 7a). Thereby, the second separating groove (second separating groove 7b) configured to separate the first cell (first semiconductor layer 3), the ZnO layer (transparent conductive layer 4) and the second cell (second semiconductor layer 5) into parts is formed. The second harmonics with a wavelength of 532 nm is used as the Nd:YAG laser beam, and the second separating groove (second separating groove 7b) is 50 μm in width, as in the example 1.

Subsequently, a ZnO layer and an Ag layer (back-surface-side conductive layer 6) and the third separating groove (third separating groove 7c) are formed in the same manner as those in the example 1.

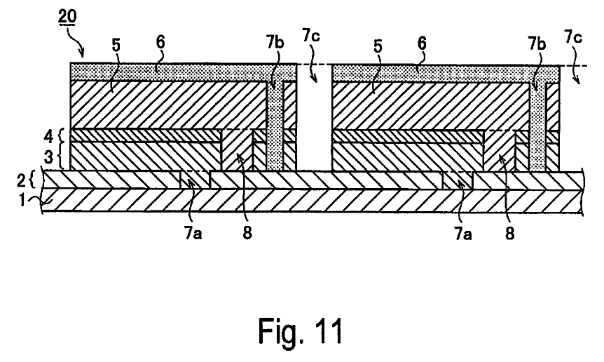

As shown in FIG. 11, through the foregoing steps, manufactured is the solar cell module 20 according to comparative example in which the transparent conductive layer separating groove (transparent conductive layer separating groove 8) and the first separating groove (first separating groove 7a) keep a distance between each other.

<Characteristics Evaluation>

Characteristic values representing the open-circuit voltage, short-circuit current, fill factor, photoelectric conversion efficiency and dead area width are compared among the solar cell modules according to examples 1 to 3 and comparative example. Results of the comparison are shown in Table 1. Note that conditions for measuring the characteristic values are AM1.5, 100 mW/cm² and 25° C.

In Table 1 below, the dead area width (unit: μm) each for examples 1 to 3 means the distance between the opposite end portion of the third separating groove (third separating groove 7c) from the transparent conductive layer separating groove (transparent conductive layer separating groove 8) and the opposite end portion of the transparent conductive layer separating groove (transparent conductive layer separating groove 8) from the third separating groove (third separating groove 7c). On the other hand, the dead area width (unit: μm) for comparative example means the distance between the opposite end portion of the third separating groove (third separating groove 7c) from the transparent conductive layer separating groove (transparent conductive layer separating groove 8) and the opposite end portion of the first separating groove (first separating groove 7a) from the transparent conductive layer separating groove (transparent conductive layer separating groove 8). The dead area width denotes an area in which the output of a current generated in the first cell (first semiconductor layer 3) and the second cell (second semiconductor layer 5) are difficult.

TABLE 1
Characteristic Values of Each of Solar Cell Modules According
to Examples 1 to 3 and Comparative Example

| | open- | | | photoelectric | Dead |
|---|---|---|---|---|---|
| | circuit | Short-circuit | | Conversion | Area |
| | voltage | current | Fill | Efficiency | Width |
| | (V) | (mA) | Factor | (%) | (μm) |
| Example 1 | 14.85 | 87.84 | 0.720 | 11.59 | 300 |
| Example 2 | 14.87 | 87.70 | 0.722 | 11.62 | 300 |
| Example 3 | 14.84 | 87.75 | 0.723 | 11.62 | 300 |
| Comparative | 14.81 | 86.47 | 0.708 | 11.18 | 370 |
| Example | | | | | |

As shown in Table 1, the photoelectric conversion efficiency of each of solar cell modules 10 according to examples 1 to 3 is better than that of solar cell module 20 according to a comparative example. One may consider that solar cell module 20 according to the comparative example has poor photoelectric conversion efficiency because solar cell module 20 is not capable of preventing leakage current, and has a larger dead area width. In contrast, it is confirmed that solar cell modules 10 according to examples 1 to 3 are capable of increasing their photoelectric conversion efficiencies in comparison with solar cell module 20 according to the comparative example. That is because solar cell modules 10 according to examples 1 to 3 prevent a leakage current, and concurrently has the smaller dead area width in comparison with solar cell module 20 according to the comparative example.

As described above, the solar cell module and the method of manufacturing the solar cell module according to each embodiment is capable of preventing a leakage current, and of preventing the second semiconductor layer from being delaminated from the translucent substrate.

The invention includes other embodiments in addition to the above-described embodiments without departing from the spirit of the invention. The embodiments are to be considered in all respects as illustrative, and not restrictive. The scope of the invention is indicated by the appended claims rather than by the foregoing description. Hence, all configurations including the meaning and range within equivalent arrangements of the claims are intended to be embraced in the invention.

What is claimed is:

1. A solar cell module comprising:
a translucent substrate;
a translucent light-receiving-surface-side conductive layer formed on a principal surface of the substrate;
a first semiconductor layer formed on a principal surface of the light-receiving-surface-side conductive layer;
a transparent conductive layer formed on a principal surface of the first semiconductor layer;
a second semiconductor layer formed on a principal surface of the transparent conductive layer;
a back-surface-side conductive layer formed on a principal surface of the second semiconductor layer;
a first separating groove configure to separate the light-receiving-surface-side conductive layer into parts, the first separating groove being filled with a material for the second semiconductor layer;
a second separating groove configured to separate the first semiconductor layer, the transparent conductive layer and the second semiconductor layer into parts, the second separating groove being filled with a material for the back-surface-side conductive layer;
a third separating groove formed in a location opposite to the first separating groove across the second separating groove and configured to separate the back-surface-side conductive layer, the second semiconductor layer and the transparent conductive layer into parts; and
a transparent conductive layer separating groove formed continuously from the first separating groove and configured to separate the transparent conductive layer and the first semiconductor layer into parts, the transparent conductive layer separating groove being filled with the material for the second semiconductor layer, wherein
the transparent conductive layer separating groove at a side of the first separating groove is larger in width than the first separating groove at a side of the transparent conductive layer separating groove.

2. The module of claim 1, wherein the second semiconductor layer essentially contains a microcrystalline semiconductor.

3. The module of claim 1, wherein, in the first separating groove, an angle between an inner wall of the first separating groove and the principal surface of the substrate is obtuse.

4. The module of claim 1, wherein the light-receiving-surface-side conductive layer essentially contains a metallic oxide including any one of tin oxide (SnO₂), zinc oxide (ZnO), indium oxide (In₂O₃) and titanium oxide (TiO₂).

5. The module of claim 4, wherein the light-receiving-surface-side conductive layer essentially contains the metallic oxide which is doped with at least any one of fluorine (F), tin (Sn), aluminum (Al), ferrum (Fe), gallium (Ga) and niobium (Ni).

6. The module of claim 1, wherein a width of the transparent conductive layer separating groove is larger than a width of the first separating groove, but not larger than 2.5 times thereof.

7. A method of manufacturing a solar cell module comprising:
forming a translucent light-receiving-surface-side conductive layer, a first semiconductor layer and a transparent conductive layer in this order on a principal surface of a translucent substrate;
removing the transparent conductive layer and the first semiconductor layer to form a transparent conductive layer separating groove configured to separate the transparent conductive layer and the first semiconductor layer into parts;
removing the light-receiving-surface-side conductive layer to form a first separating groove configured to separate the light-receiving-surface-side conductive layer into parts, wherein the first separating groove and the transparent conductive layer separating groove are continuous to each other, and the first separating groove is smaller in width than the transparent conductive layer separating groove;
forming a second semiconductor layer on the transparent conductive layer while filling a material for the second semiconductor layer in the first separating groove and the transparent conductive layer separating groove;
removing the first semiconductor layer, the transparent conductive layer and the second semiconductor layer to form a second separating groove configured to separate the first semiconductor layer, the transparent conductive layer and the second semiconductor layer into parts;
forming a back-surface-side conductive layer on the second semiconductor layer while filling a material for the back-surface-side conductive layer in the second separating groove; and
removing the back-surface-side conductive layer, the second semiconductor layer and the transparent conductive layer to form a third separating groove configured to separate the back-surface-side conductive layer, the second semiconductor layer and the transparent conductive layer into parts in a location opposite to the first separating groove across the second separating groove.

8. The method of claim 7, wherein the second semiconductor layer essentially contains a microcrystalline semiconductor.

9. The method of claim 7, wherein, in the first separating groove, an angle between an inner wall of the first separating groove and the principal surface of the substrate is obtuse.

10. The method of claim 7, wherein the light-receiving-surface-side conductive layer essentially contains a metallic oxide including any one of tin oxide (SnO₂), zinc oxide (ZnO), indium oxide (In₂O₃) and titanium oxide (TiO₂).

11. The method of claim 10, wherein the light-receiving-surface-side conductive layer essentially contains the metallic oxide which is doped with at least any one of fluorine (F), tin (Sn), aluminum (Al), ferrum (Fe), gallium (Ga) and niobium (Ni).

12. The method of claim 7, wherein a width of the transparent conductive layer separating groove is larger than a width of the first separating groove, but not larger than 2.5 times thereof.

13. A method of manufacturing a solar cell module comprising:
forming a translucent light-receiving-surface-side conductive layer on a principal surface of a translucent substrate;
removing the light-receiving-surface-side conductive layer to form a first separating groove configured to separate the light-receiving-surface-side conductive layer into parts;
forming a first semiconductor layer on the light-receiving-surface-side conductive layer while filling a material for the first semiconductor layer in the first separating groove;
forming a transparent conductive layer on the first semiconductor layer;
removing the first semiconductor layer filled in the first separating groove and further removing the first semiconductor layer and the transparent conductive layer to separate the transparent conductive layer and the first semiconductor layer into parts, thereby forming a transparent conductive layer separating groove which is continuous to the first separating groove, and is larger in width than the first separating groove;
forming a second semiconductor layer on the transparent conductive layer while filling a material for the second semiconductor layer in the first separating groove and the transparent conductive layer separating groove;
removing the first semiconductor layer, the transparent conductive layer and the second semiconductor layer to form a second separating groove configured to separate the first semiconductor layer, the transparent conductive layer and the second semiconductor layer into parts;
forming aback-surface-side conductive layer on the second semiconductor layer while filling the back-surface-side conductive layer in the second separating groove; and
removing the back-surface-side conductive layer, the second semiconductor layer and the transparent conductive layer to form a third separating groove in a location opposite to the first separating groove across the second separating groove, the third separating groove configured to separate the back-surface-side conductive layer, the second semiconductor layer and the transparent conductive layer into parts.

14. The method of claim 13, wherein the second semiconductor layer essentially contains a microcrystalline semiconductor.

15. The method of claim 13, wherein, in the first separating groove, an angle between an inner wall of the first separating groove and the principal surface of the substrate is obtuse.

16. The method of claim 13, wherein the light-receiving-surface-side conductive layer essentially contains a metallic oxide including any one of tin oxide (SnO₂), zinc oxide (ZnO), indium oxide (In₂O₃) and titanium oxide (TiO₂).

17. The method of claim 16, wherein the light-receiving-surface-side conductive layer essentially contains the metallic oxide which is doped with at least any one of fluorine (F), tin (Sn), aluminum (Al), ferrum (Fe), gallium (Ga) and niobium (Ni).

18. The method of claim 13, wherein a width of the transparent conductive layer separating groove is larger than a width of the first separating groove, but not larger than 2.5 times thereof.
